(19) United States
(12) Patent Application Publication
(10) Pub. No.: US 2006/0257754 A1
(43) Pub. Date: Nov. 16, 2006

(54) Pellicles having low adhesive residue

(75) Inventors: Katsuaki Harubayashi, Kuga-gun (JP); Minoru Fujita, Iwakuni-shi (JP); Masahiro Kondou, Iwakuni-shi (JP); Yoshihisa Saimoto, Minato-ku (JP)

Correspondence Address: BUCHANAN, INGERSOLL & ROONEY PC, POST OFFICE BOX 1404, ALEXANDRIA, VA, 22313-1404, US

(73) Assignee: MITSUI CHEMICALS, INC., Minato-ku (JP)

(21) Appl. No.: 11/429,955

(22) Filed: May 9, 2006

(30) Foreign Application Priority Data
May 9, 2005 (JP) 2005-135721

(51) Int. Cl. A47G 1/12; G03F 1/14; G03F 1/00; G03C 5/00

(52) U.S. Cl. 430/5; 428/14; 430/322; 430/323

(57) ABSTRACT

The present invention provides a pellicle, wherein a peel strength is from 0.004 N/mm to 0.10 N/mm when a non-surface-treated polyethylene terephthalate film having a thickness of 125 μm is peeled in a direction of 180 degrees at a temperature of 23° C. after the polyethylene terephthalate film has been adhered to the mask adhering surface of the pellicle.

The present application claims priority under 35USC119 from Japanese Patent Application No. 2005-135721, the disclosure of which is incorporated by reference herein.

### BACKGROUND OF THE INVENTION

1. Field of the Invention

The present invention relates to a pellicle used in a semiconductor photolithographic process that is one of semiconductor processes for the purpose of preventing dust from adhering to a reticle or photomask (hereinafter simply referred to as a photomask). More specifically, the invention relates to a pellicle having a low adhesive residue remaining on the surface of a photomask, where part of the mask adhesive of the pellicle becomes removed and transferred onto the surface of the photomask, when peeling the pellicle from the photomask after use.

2. Description of the Related Art

Pellicles have been used as dust-proof covers for photomasks in a semiconductor lithographic process that is one of the semiconductor processes. A mask adhesive, for maintaining adhesion of the pellicle to a photomask, is required to have a high adhesiveness to the surface of the photomask in order to exert a high dust-proofing effect, and is also required to be easily removed during use when foreign substance becomes adhered to an unacceptable extent or when a pellicle film is damaged. Since such characteristics greatly affect the convenience when using the photomask, various schemes, such as control of hardness of the mask adhesive and the like, have been devised as disclosed, for example, in Japanese Patent Laid-Open (JP-A) No. 10-282640.

Conventionally used mask adhesives, such as disclosed in JP-A 10-282640 and the like, have sufficient adhesiveness for exhibiting dust-proofing property and can easily be removed. However, there has been a problem that, because of adhesive residue remaining on almost the entire adhesion surface, where part of the mask adhesive becomes removed and transferred onto the surface of the photomask when peeling the pellicle from the photomask, adequate washing is needed in order to recycle the photomask. In particular, the miniaturization of semiconductor fabrication recently progressed so that strict cleanliness of the surface of photomasks is demanded, while, similarly, the surface structure of photomasks has become more sophisticated and delicate for microfabrication for semiconductors so that washing has become difficult or damage easier. For this reason, there has been strongly demanded a pellicle having a mask adhesive with sufficient adhesiveness at the time of attachment, yet giving little adhesive residue on a surface of a photomask to such an extent that washing is easily carried out after peeling the pellicle, or more preferably washing is not necessary.

In order to reduce adhesive residue on the surface of a photomask at the time of peeling off a pellicle, the cohesive force of a mask adhesive is required to be stronger than the adhesive force at the adhesion interface. However, in a semiconductor lithographic process, since the pellicle as described above is strictly required to be tightly adhered to the surface of the photomask, it has been considered difficult to lower the adhesive force at the adhesion interface. In short, since the control range of the cohesive force inside the mask adhesive and the adhesive force of the adhesion interface is greatly limited, occurrence of the adhesive residue of the mask adhesive on the surface of the photomask has been considered inevitable.

As methods for adhering and maintaining a pellicle onto a photomask without using an adhesive, a method of applying a reduced pressure suction and a method of applying a magnetic force have been disclosed in Japanese Patent Laid-Open (JP-A) No. 61-245163 and in Japanese Patent Laid-Open (JP-A) No. 62-109053 respectively. In these methods, adhesive residue attributed to a mask adhesive does not occur at the time of peeling the pellicle. However, the structure of the pellicle is very different from that of a conventional pellicle and, when the pellicle is used in practice, dramatic changes in ancillary facilities are required. Accordingly, it cannot be said that these methods are practical.

On the other hand, also in a wafer protective film in a semiconductor wafer polishing process, which is a totally different application, a protective film that does not cause an adhesive residue on the wafer surface at the time of peeling off the film has been required, and various investigations have been made into adhesives. Japanese Patent Laid-Open (JP-A) No. 4-186832 discloses a wafer protective film with reduced adhesive residue by adding a reactive surfactant at the time of polymerization reaction in preparing the adhesive. Further, Japanese Patent Laid-Open (JP-A) No. 1993-198542 discloses a wafer protective film with reduced adhesive residue by suppressing an initial peeling strength to be low and regulating the adhesive strength to increase with elapse of time.

However, since the adhesive strength of adhesives for use in these wafer protective films is extremely weak as compared with that of mask adhesives of a pellicle, the very high adhesiveness to a photomask that is required for a pellicle cannot be considered exhibited at all.

The present invention has been made under the above circumstances and provides pellicles having a low adhesive residue.

The present inventor has been actually tested an emulsion type adhesive among adhesives used for wafer protective films as a mask adhesive of a pellicle even though the adhesive strength of the emulsion type adhesive itself is low, and as a result, has found that there is a possibility to satisfy adhesiveness necessary for putting a pellicle into practical use, has confirmed that an adhesive residue remained on a surface of a photomask at the time of peeling is very small, and has repeatedly conducted a study. Thus, the present invention has been completed.

### SUMMARY OF THE INVENTION

That is, the present invention relates to a pellicle comprising a pellicle film which is stretched on one end surface of a frame via a film adhesive and a mask adhesive layer to be adhered to a photomask on the other end surface of the frame, wherein an area of an adhesive residue of a mask adhesive remaining on a surface of a quartz glass when the mask adhesive surface is adhered to the quartz glass followed by peeling is not more than 5% of an area of an adhesion surface.

Furthermore, the mask adhesive layer in the present invention is capable of adhering and holding the pellicle to the photomask and comprises a layer forming a surface in contact with the photomask. The mask adhesive layer may have a multi-layer structure comprising a plurality of layers and does not necessarily mean to include a layer having a single layer. In order to emphasize inclusion of the multi-layer structure as well, the mask adhesive layer is termed “mask adhesive layers”, and among these layers, a single phase of an adhesive which constitutes a surface in contact with the photomask is termed “mask adhesive” in order to distinguish from each other. Unless otherwise specified, the term “mask adhesive layers” may include a layer having a single phase formed only of the mask adhesive.

### BRIEF DESCRIPTION OF THE DRAWINGS

FIG. 1 is a partial cross-sectional view illustrating configuration of a pellicle according to one of embodiments (Example 1) of the present invention.

FIG. 2 is a microscopic photograph of an adhered surface of a quartz glass according to Example 1.

FIG. 3 is a microscopic photograph of an adhered surface of a mask blank according to Example 2.

FIG. 4 is a microscopic photograph of an adhered surface of a quartz glass according to Comparative Example 1.

FIG. 5 is a microscopic photograph of an adhered surface of a mask blank according to Comparative Example 2.

### DETAILED DESCRIPTION OF THE INVENTION

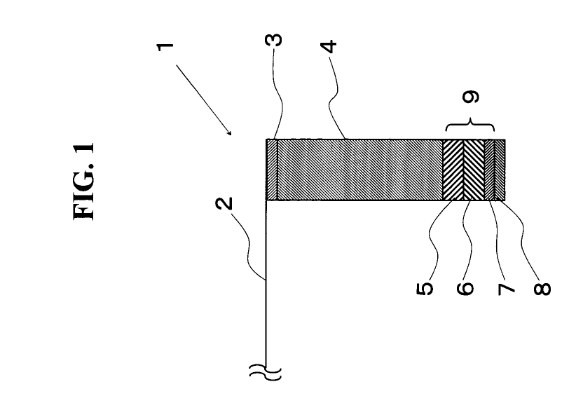

As shown in FIG. 1, the pellicle 1 of the present invention comprises a frame 4, a pellicle film 2 which is stretched on one end surface of the frame 4 via a film adhesive 3 and a mask adhesive layer 9 to be adhered to a photomask placed on the other end surface of the frame 4.

When the pellicle is adhered to the quartz glass followed by peeling the pellicle, the mask adhesive of the present invention has an area of an adhesive residue which is peeled and transferred onto a surface of the quartz glass, and remained thereon, and which is not more than 5% of an area of an adhesion surface. When a pellicle having such a mask adhesive is used, an adhesive residue on the photomask is very small so that washing of the photomask is completed in a very simple manner or washing is not necessary.

An area of the adhesive residue is calculated by summing up areas of parts where an adhesive residue is visually confirmed. To confirm occurrence of the adhesive residue, the pellicle and quartz glass are maintained under the environmental conditions at a temperature of 23° C. and a humidity of 55% RH for 12 hours, and a load of 1.5×10² N is applied over 3 minutes under the same environmental conditions for adhering the pellicle to the quartz glass, the resulting material is kept without a load for 1 week, the pellicle is peeled off from the quartz glass, and the surface of the quartz glass is observed using a microscope.

In order to reduce the adhesive residue when the pellicle is peeled off as described above, it is preferable to use a mask adhesive with a peeling strength of from 0.004 N/mm to 0.10 N/mm relative to a non-surface-treated polyethylene terephthalate having a thickness of 125 μm at 23° C. When the peeling strength is greater than 0.10 N/mm, the adhesive residue of the mask adhesive may be remarkable, thereby possibly making washing of the photomask difficult. On the other hand, when the peeling strength is less than 0.004 N/mm, the adhesiveness of the pellicle to the photomask may be insufficient, thereby possibly making an inherent dust resistance of the pellicle deteriorated.

The peeling strength is measured according to the following method that is widely used as a method for evaluating the adhesiveness of an adhesive film and the like. Namely, the mask adhesive is evenly and smoothly formed. Thereafter, a non-surface-treated polyethylene terephthalate film (a product of Toray Industries, Inc., trade name: Lumilar S10#125) having a thickness of 125 μm is adhered to the surface of the formed mask adhesive as an adherend, and the resulting material is adhered at a pressure of 2.0×10⁵ Pa for 3 minutes. Subsequently, under the environmental condition of 23° C., the film is pulled at a rate of 10 mm/min in a direction of 180 degrees to the adhered surface and peeled off, and a maximum load value measured at this time is regarded as the peeling strength.

At the time of the measurement, a method for forming a material used for the surface which is brought into contact with the mask of the mask adhesive may be appropriately selected depending on characteristics of the material. However, for example, since the mask adhesive applied to the pellicle is evenly and smoothly formed on one end surface of the frame, the mask adhesive can be used for the measurement of the peeling strength as it is.

The mask adhesive having the aforementioned peeling strength is not particularly restricted. However, an acrylic type emulsion adhesive or a synthetic rubber type emulsion (latex) adhesive can be used. A so-called micro sucker with fine depressed pores formed on a surface of the adhesive due to bubbles or foams formed by blowing bubbles or the like can also be used. As the synthetic rubber type adhesive, preferably used are latex adhesives such as a styrene-butadiene type copolymer (SBR), a polybutadiene type polymer (BR), a methyl methacrylate-butadiene type copolymer (MBR), an acrylonitrile-butadiene type copolymer (NBR), a chloroprene type polymer (CR), carboxyl-modified products thereof and the like. Particularly preferably used is an acrylic type emulsion adhesive obtained by emulsion polymerization of an acrylic type monomer such as acrylic acid, methacrylic acid, an ester or amide of acrylic acid, an ester or amide of methacrylic acid, acrylonitrile and the like.

These acrylic type emulsion adhesives preferably contain a surfactant, and may also contain a cross-linking agent or a water-soluble organic compound. The surfactant may be added after polymerization of an adhesive or during polymerization of an adhesive, and may be a polymerizable surfactant capable of reacting by itself at the time of polymerization or other types different therefrom may be used. Specific examples of the emulsion adhesive are disclosed on page 2 of Japanese Patent Application Laid-Open No. 4-186831, and Paragraph Nos. (0029)-(0038) of Japanese Patent Application Laid-Open No. 5-198542 in detail, and those emulsion adhesives can suitably be used in the present invention. For example, acrylic emulsion adhesives obtained by emulsion-polymerizing a monomer mixture containing an alkyl acrylate monomer or an alkyl methacrylate monomer, and a monomer containing carboxylic groups in a deionized aqueous medium containing an emulsifier, a polymerization initiator and the like can be used. The monomer mixture may further contain a monomer which is polymerizable with the monomers, as occasion demands. The alkyl acrylate monomer or alkyl methacrylate monomer include, for example, methyl acrylate, methyl methacrylate, ethyl acrylate, ethyl methacrylate, propyl acrylate, propyl methacrylate, butyl acrylate, butyl methacrylate, hexyl acrylate, hexyl methacrylate, octyl acrylate, octyl methacrylate, nonyl acrylate, nonyl methacrylate, dodecyl acrylate and dodecyl methacrylate. These alkyl groups may be linear or branched. The alkyl acrylate monomer or alkyl methacrylate may be used singly or in combination.

The above monomer containing a carboxyl group includes, for example, an acrylic acid, methacrylic acid, crotonic acid, itaconic acid, maleic acid, fumaric acid and the like. The amount of the monomers having these carboxylic groups to be used is preferably about 0.1 to 10 parts by weight based on 100 parts by weight of the monomer mixture which forms an acrylic emulsion adhesive. The carboxylic groups in the adhesive react with a crosslinking agent to form a crosslinked structure. Accordingly, when the amount of the monomer having carboxylic groups is less than 0.1 parts by weight, the crosslinked structure is not sufficiently formed, and there is a fear of an insufficient cohesive force. In contrast, when the amount of the monomer having carboxylic groups is more than 10 parts by weight, there is a fear that the reaction system in the emulsion polymerization becomes unstable.

The vinyl monomers include, for example, hydroxyethyl acrylate, hydroxyethyl methacrylate, hydroxypropyl acrylate, hydroxypropyl methacrylate, acrylamide, methacrylamide, dimethylamino acrylate, dimethylamino methacrylate, vinylacetate, styrene, acrylonitrile and the like.

The surfactants include, for example, polyoxyalkylene alkylethers such as polyoxyethylene laurylether and polyoxyethylene stearylether, polyoxyethylene alkylesters such as polyoxyethylene laurylester and polyoxyethylene stearylester, polyoxyethylene alkylphenylethers such as polyoxyethylene octylphenylether, polyoxyethylene nonylphenylether, sorbitanalkylesters such as sorbitan monolaurate, sorbitam monopalmitate and sorbitan monostearate, and polyoxyethylene sorbitan alkylesters such as polyoxyethylene sorbitol laurate, polyoxyenylene sorbitol oleatelaurate, polyoxyalkylenes such as polyoxyethylene, polyoxypropylene and polyoxyethylenepolyoxypropylene glycol, polyoxyethylene alkylamides, and the like.

The addition amount of the surfactants is preferably about 0.05 to 10 parts by weight, preferably about 0.5 to 3 parts by weight with respect to 100 parts of solid portion in the acrylic emulsion adhesive.

Although the mask adhesive layer may comprise a single layer formed of an adhesive alone to be used for a surface to be adhered to the photomask, as long as the adhesive to be used for the surface to be adhered to the photomask has the peeling strength as described above, the mask adhesive layer may be of a multi-layer structure comprising other layers.

The thickness of the mask adhesive layer is not particularly limited, but, when the mask adhesive layer is formed by a single layer of a mask adhesive, the adhesive layer having a thickness of about 5 to 100 μm, preferably 10 to 50 μm can allow a pellicle to adhere the photomask.

The thickness of the mask adhesive layer having the above-described three-layer structure is preferably about 50 to 2500 μm, more preferably about 75 to 600 μm, in light of adhesive condition. In this case, when the thickness of the base material adhesive is about 10 to 2000 μm, preferably about 100 to 800 μm, the thickness of the film base material is about 5 to 500 μm, preferably about 10 to 200 μm, and the thickness of the mask adhesive layer is about 5 to 100 μm, preferably about 10 to 50 μm, the pellicle can suitably adhere to the photomask.

For example, as shown in FIG. 1, the mask adhesive layer 9 may be of a 3-layer structure comprising a base material adhesive 5, a film base material 6 and a mask adhesive 7 in this order from the frame 4 side. Using such a configuration, the mask adhesive layer has an advantage such that an operation for producing a pellicle 1 becomes easy. That is, the pellicle having the configuration of the mask adhesive layer 9 can be produced in such a manner that the film base material 6 provided with the mask adhesive 7 on one surface previously is adhered to the frame 4 via the base material adhesive 5 at the other surface of the film base material. The base material adhesive 5 herein may be coated on the frame 4 in advance or the base material adhesive 5 may be coated on the other surface of the film base material 6.

Furthermore, when the pellicle 1 is actually used, a protective film 8 called a liner is preferably adhered to the mask adhesive surface until the pellicle is adhered to the photomask.

The mask adhesive and the base material adhesive can be coated on the film base material, using conventionally known coating methods. For example, a roller coating method, a flow coating method and the like can be used for coating. In order to coat the base material adhesive on the frame, conventionally known methods can be used for coating. For example, a hot melt method for coating a molten adhesive or the like can be used.

A material to be used for the film base material to be coated with the mask adhesive is not particularly limited, but a film comprising a thermoplastic resin is preferably used because a desired thickness or desired physical properties can be easily obtained. Specifically, a film comprising polyester such as polyethylene terephthalate, polyethylene naphthalate or the like, polyolefin such as polyethylene, polypropylene or the like, a vinyl type polymer such as ethylene vinyl acetate copolymer or the like can be appropriately used. These thermoplastic films may be stretched for the purpose of controlling the physical properties thereof.

The base material adhesive for adhering the film base material provided with the mask adhesive on one surface thereof to the frame is not particularly limited as long as the base material adhesive is capable of adhering the film base material to the frame. However, the JIS hardness value of the base material adhesive is preferably from 0.6 N to 2.9 N. When the JIS hardness value of the base material adhesive is less than 0.6 N, the mask adhesive layer may be deformed during storage of the pellicle or at the time of use thereof, thereby possibly deteriorating adhesiveness. Further, when the JIS hardness value of the base material adhesive is more than 2.9 N, the adhesiveness to the photomask may be worsened. Furthermore, the JIS hardness value in the present invention can be measured in accordance with JIS K6301 (corresponding to ASTM D2240), using, for example, a rubber hardness tester GS-706 (JIS A type) (a product of Teclock).

As the base material adhesive, any adhesives may be used as long as they can allow the film base material to adhere the frame. Specific examples thereof preferably include a hot melt type resin such as a styrene-ethylene-butylene-styrene block copolymer (SEBS), a styrene-ethylene-propylene-styrene block copolymer (SEPS), an ethylene vinyl acetate resin, a butyl methacrylic resin, polystyrene, polyisobutylene or copolymers thereof, or an adhesive produced by appropriately adding other resin, an adhesiveness-imparting agent, a thickening agent, an anti-oxidant, a stabilizer or the like to an adhesive resin such as silicone type, urethane type, acrylic type or the like.

As long as the pellicle of the present invention has the mask adhesive layer, other structural elements or configurations are not particularly limited. For example, the material or thickness of the pellicle film, the material or structure of the frame, structures so as not to apply a load to the pellicle film by expansion or shrinkage of interior gas thereof, structures for preventing dust generation from the frame, structures so as not to deform the frame due to tension of the pellicle film and the like are not particularly limited in the pellicle of the present invention.

### EXAMPLES

The present invention is now more specifically illustrated below with reference to Examples and the like. However, the scope of the present invention is not restricted to these Examples and the like.

### Example 1

Into a flask equipped with a thermometer, a reflux condenser, a dropping funnel, a nitrogen gas inlet and a stirrer were added 150 parts by weight of an ion exchange water and 2 parts by weight of a compound with an allyl group added to a benzene ring of polyoxyethylene nonylphenyl ether (20 moles of ethylene oxide added) as a surfactant, and the temperature of the resulting mixture was raised to 70° C. with stirring under nitrogen atmosphere.

Then, 0.5 part by weight of ammonium peroxysulfate as a polymerization initiator was added thereto and was dissolved. Further, 100 parts by weight of a monomer mixture containing 70 parts by weight of 2-ethylhexyl acrylate, 25 parts by weight of methyl methacrylate, 3 parts by weight of methacrylic acid and 2 parts by weight of 2-hydroxyethyl acrylate was continuously added dropwise over 4 hours and further continuously stirred for another 3 hours even after the dropwise addition was completed for polymerization to obtain an acrylic type emulsion adhesive having a solid content of about 40% by weight.

Subsequently, to 100 weight parts of the adhesive was added 10 parts by weight of diethylene glycol monobutyl ether to obtain a coating solution. The resulting coating solution was coated on one corona-treated surface of a polyethylene terephthalate film having a thickness of 75 μm using a roll coater and the resulting material was dried at 105° C. to obtain a film base material provided with a mask adhesive having a thickness of 10 μm.

Then, a protective film was adhered onto a mask adhesive coated surface of the film base material.

A base material adhesive having a thickness of 400 μm was coated on the mask adhered surface of the pellicle frame using A131 (JIS hardness: 2.2 N, a product of Asahi Chemical Synthetic Co., Ltd.), i.e., a SEBS-based hot melt adhesive by a hot melt method. Subsequently, a surface, on which the mask adhesive was not coated, of the film base material coated with the mask adhesive was adhered to the frame to produce a pellicle having a configuration as illustrated in FIG. 1.

The protective film adhered to the mask adhesive was peeled off from the pellicle obtained according to the aforementioned method and Lumilar (trade name) S10#125 grade (a product of Toray Industries, Inc.), i.e., a non-surface-treated polyethylene terephthalate film having a thickness of 125 μm was stuck onto the surface thereof and was adhered at a pressure of 2.0×10⁵ Pa for 30 seconds. Then, the polyethylene terephthalate film was pulled at a rate of 10 mm/min in a direction of 180 degrees relative to the adhered surface under the environmental condition of 23° C. and peeled off to measure a peeling strength. The resulting peeling strength was 0.04 N/mm.

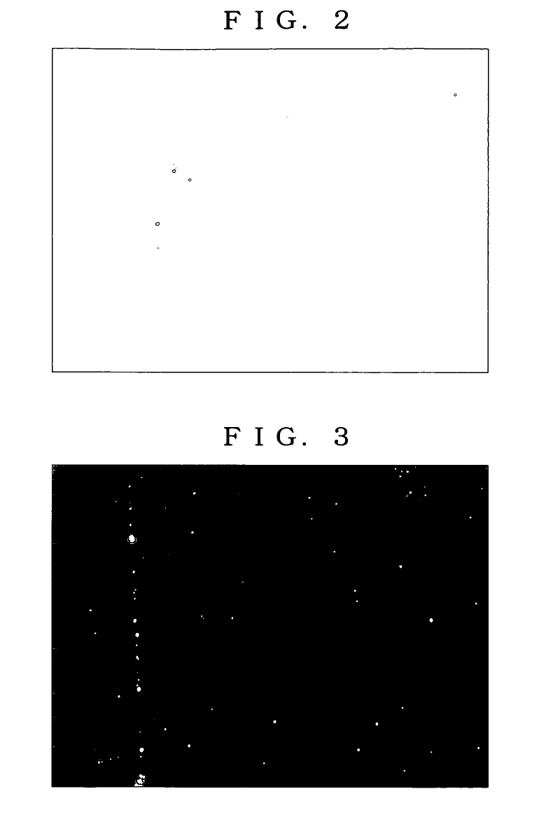

Another pellicle obtained according to the aforementioned method and a quartz glass were kept at a room maintained at a temperature of 23° C. and a humidity of 55% RH for 12 hours, and thereafter, the protective film adhered to the mask adhesive was peeled off from the pellicle in the same environmental conditions, and was adhered to the quartz glass. After applying a load of 1.5×10² N for 3 minutes, the resulting material was kept without a load in the same environmental condition for 1 week. Subsequently, the pellicle was peeled off from the quartz glass and an adhesion surface of the quartz glass was observed using an optical microscope. At this time, an image observed at 200 magnifications is shown in FIG. 2. The image contains an adhesion surface at the left side, and a non-adhesion surface at the right side of the photograph, but difference between the adhesion surface and the non-adhesion surface cannot clearly observed. The image was subjected to a digital image processing and an area with an adhesive residue remained on the adhesion surface was calculated as compared with the non-adhesion surface. As a result, the area with an adhesive residue of the mask adhesive remained was about 0.2% of the whole adhesion surface area.

### Example 2

The pellicle produced in Example 1 and a mask blank (trade name: EQZ VTL 625-2QZ, a product of Hoya Corporation, hereinafter referred to as “mask blank”) were kept at a room maintained at a temperature of 23° C. and a humidity of 55% RH for 12 hours, and thereafter, the protective film adhered to the mask adhesive was peeled off from the pellicle in the same environment and was adhered to the mask blank. After applying a load of 1.5×10² N for 3 minutes, the resulting material was kept without applying a load thereto in the same environmental condition for 1 week. Subsequently, the pellicle was peeled off from the mask blank and an adhesion surface of the mask blank was observed using an optical microscope. At this time, an image observed at 200 magnifications was illustrated in FIG. 3. The image includes an adhesion surface at left side and a non-adhesion surface at the right side of the image, but difference between the adhesion surface and the non-adhesion surface cannot clearly observed. The image was subjected to a digital image processing and an area with an adhesive residue remained on the adhesion surface was calculated as compared with the non-adhesion surface. As a result, the area with an adhesive residue of the mask adhesive remained thereon was about 1.8% of the entire adhesion surface area. Since generation of the adhesive residue was slight, even if the pellicle was adhered to the mask blank again without washing, it was confirmed that there was no problem in adhesiveness.

Furthermore, a mask blank refers to a laminate with a metal thin film coated on a quartz glass, and a circuit to be transferred onto a semiconductor wafer in a semiconductor lithographic process is drawn on a mask blank to obtain a mask. Accordingly, a mask blank refers to a photomask on which a circuit is not drawn. When an adhesive residue of a pellicle is evaluated, the obtained results can be closer to those in the actual use environment by using the mask blank.

### Comparative Example 1

A base material adhesive having a thickness of 400 μm was coated on the mask adhesion surface of the pellicle frame using A131 (JIS hardness: 2.2 N, a product of Asahi Chemical Synthetic Co., Ltd.), i.e., a SEBS-based hot melt adhesive by a hot melt method. Subsequently, Lumilar (trade name) S10#125 grade (a product of Toray Industries, Inc.), i.e., a non-surface-treated polyethylene terephthalate film having a thickness of 125 μm was stuck on the mask adhesive and was adhered thereto at a pressure of 2.0×10⁵ Pa for 30 seconds. Thereafter, the polyethylene terephthalate film was pulled at a rate of 10 mm/min in a direction of 180 degrees relative to the adhesion surface in an environmental condition of 23° C. and peeled off to measure a peeling strength. The resulting peeling strength was 0.18 N/mm.

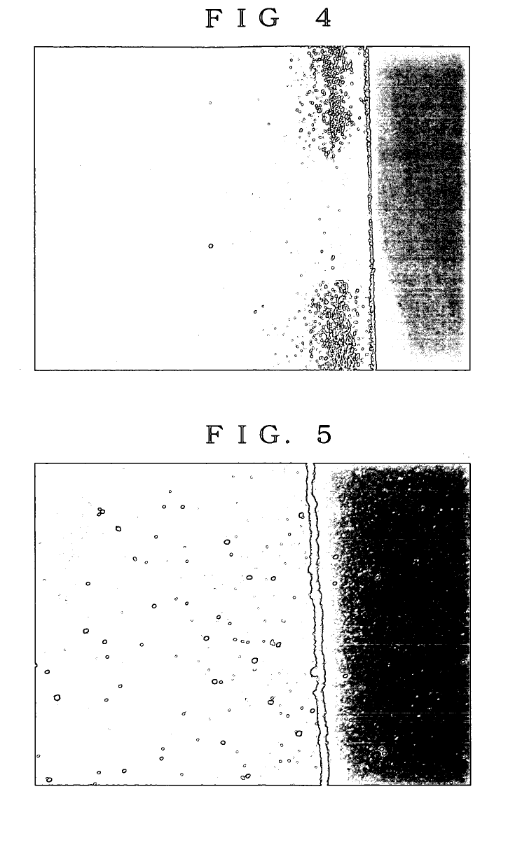

A base material adhesive having a thickness of 400 μm was coated on the mask adhesion surface of the pellicle frame using A131 (JIS hardness: 2.2 N, a product of Asahi Chemical Synthetic Co., Ltd.), i.e., a SEBS-based hot melt adhesive by a hot melt method. Subsequently, the pellicle frame and quartz glass were kept at a room maintained at a temperature of 23° C. and a humidity of 55% RH for 12 hours, and thereafter, the protective film adhered to the mask adhesive was peeled off from the pellicle in the same environmental condition and adhered to the quartz glass. After applying a load of 1.5×10² N for 3 minutes, the resulting material was kept without a load in the same environmental condition for 1 week. Subsequently, the pellicle was peeled off from the quartz glass and the adhesion surface of the quartz glass was observed using an optical microscope. At this time, an image observed at 200 magnifications was illustrated in FIG. 4.

The image includes an adhesion surface of about 80% at the left side and non-adhesion surface of about 20% at the right side of the image. A boundary between the adhesion surface and the non-adhesion surface can be distinguishable by a vertical white line. The adhesive residue is observed on the entire contact surface. The image was subjected to a digital image processing and an area with an adhesive residue remained on the adhesion surface was calculated as compared with the non-adhesion surface. As a result, the area with an adhesive residue remained was 100% of the adhesion surface area.

### Comparative Example 2

An adhesive residue on a mask blank was evaluated in the same manner as in Comparative Example 1, except that a mask blank was used instead of the quartz glass as an adherend. As a result, an area of the adhesive residue remained on the mask blank was 100% of the adhesion area obtained from the digital image processing. At this time, an image observed at 200 magnifications was illustrated in FIG. 5. About of the image includes about 70% of an adhesion surface at the left side and about 30% of a non-adhesion surface at the right side of the image. . A boundary between the adhesion surface and the non-adhesion surface can be distinguishable by a vertical white line. In order to obtain the necessary adhesiveness when the pellicle was adhered to the mask blank again, it was confirmed that sufficient washing was necessary.

The present invention comprises the following embodiments.

The present invention relates to a pellicle comprising a pellicle film which is stretched on one end surface of a frame with a film adhesive therebetween and a mask adhesive layer to be adhered to a photomask on the other end surface of the frame, wherein when the mask adhesive surface is adhered to the quartz glass surface followed by peeling off the pellicle the area having an adhesive residue of a mask adhesive remaining on the quartz glass surface is not more than 5% of the adhesion surface area.

Further, the present invention relates to a pellicle comprising: a pellicle film which is stretched onto one end surface of a frame with a film adhesive therebetween: and a mask adhesive layer to be adhered to a photomask on the other end surface of the frame, wherein a peeling strength is from about 0.004 N/mm to 0.10 N/mm when a non-surface-treated polyethylene terephthalate film having a thickness of 125 μm is peeled in a direction of 180 degrees at a temperature of 23° C. after the polyethylene terephthalate film has been adhered to the mask adhering surface of the pellicle.

Further, the present invention relates to a pellicle, wherein the mask adhesive of the pellicle is an acrylic type emulsion adhesive.

Further, the present invention relates to a pellicle, wherein the mask adhesive is applied onto one end surface of the film base material and the other end surface of the film base material is adhered to the frame with the base material adhesive therebetween.

Further, the present invention relates to a pellicle, wherein the mask adhesive layer comprises a layer having a JIS hardness value of from about 0.6 N to 2.9 N.

Further, the present invention relates to a process for producing the pellicle, in which a film base material coated with a mask adhesive at one end surface thereof is adhered to a frame with the base material adhesive therebetween at the other end surface thereof.

The pellicle according to the present invention has a very low adhesive residue caused by transferring and remaining a part of the mask adhesive on a photomask when the pellicle is peeled from the photomask, so that it is very simple to wash the photomask or it is not necessary to wash the photomask. Therefore, such pellicles are highly industrially valuable. Further, according to a process for producing the pellicle of the present invention, the pellicle can be prepared simply and at a low cost.

According to the present invention, it is possible to provide a pellicle having a very low adhesive residue which remains on a surface of the photomask such that a part of the mask adhesive is peeled off and transferred onto the photomask at the time of peeling the pellicle from the photomask. For this reason, washing of the photomask is very simple or becomes unnecessary. As a result, a semiconductor lithographic process becomes efficient, thus leading to reduction of cleaning solution and the like.

What is claimed is:

1. A pellicle comprising: a pellicle film, which is stretched onto one end surface of a frame with a film adhesive therebetween; and a mask adhesive layer, to be adhered to a photomask, on the other end surface of the frame, wherein when the mask adhesive surface is adhered to a quartz glass surface followed by peeling off the pellicle the area of adhesive residue of mask adhesive remaining on the quartz glass surface is not more than 5% of the adhesion surface area.

2. A pellicle comprising: a pellicle film, which is stretched onto one end surface of a frame with a film adhesive therebetween; and a mask adhesive layer, to be adhered to a photomask, on the other end surface of the frame, wherein a peel strength is from about 0.004 N/mm to 0.10 N/mm when a non-surface-treated polyethylene terephthalate film having a thickness of 125 μm is peeled in a direction of 180 degrees at a temperature of 23° C. after the polyethylene terephthalate film has been adhered to the mask adhering surface of the pellicle.

3. The pellicle according to claim 1, wherein the mask adhesive is an acrylic type emulsion adhesive.

4. The pellicle according to claim 2, wherein the mask adhesive is an acrylic type emulsion adhesive.

5. The pellicle according to claim 1, wherein the mask adhesive layer is of a multi-layer structure comprising: a mask adhesive that is an acrylic type emulsion adhesive; a film base material retaining the mask adhesive; and a base material adhesive for adhering to the frame the film base material retaining the mask adhesive.

6. The pellicle according to claim 2, wherein the mask adhesive layer is of a multi-layer structure comprising: a mask adhesive that is an acrylic type emulsion adhesive; a film base material retaining the mask adhesive; and a base material adhesive for adhering to the frame the film base material retaining the mask adhesive.

7. The pellicle according to clam 5, wherein the base material adhesive comprises a layer having a JIS hardness value of from about 0.6 N to 2.9 N.

8. The pellicle according to claim 6, wherein the base material adhesive comprises a layer having a JIS hardness value of from about 0.6 N to 2.9 N.

9. A process for producing the pellicle as described in claim 5, in which the film base material is coated with the mask adhesive on one surface of the film base material, and the other surface of the film base material is adhered to the frame with the base material adhesive therebetween.

10. A process for producing the pellicle as described in claim 6, in which the film base material is coated with the mask adhesive on one surface of the film base material, and the other surface of the film base material is adhered to the frame with the base material adhesive therebetween.
